(19) United States
(12) Patent Application Publication
(10) Pub. No.: US 2007/0285903 A1
(43) Pub. Date: Dec. 13, 2007

(54) Multilayer printed circuit board and a liquid crystal display unit

(75) Inventor: Shinichi Tomari, Kanagawa (JP)

Correspondence Address: YOUNG & THOMPSON, 745 SOUTH 23RD STREET, 2ND FLOOR, ARLINGTON, VA, 22202, US

(73) Assignee: NEC LCD TECHOLOGIES, LTD., KAWASAKI (JP)

(21) Appl. No.: 11/798,555

(22) Filed: May 15, 2007

(30) Foreign Application Priority Data
May 25, 2006 (JP) 2006-145529

(51) Int. Cl. H05K 7/00

(52) U.S. Cl. 361/748

(57) ABSTRACT

The present invention provided a multilayer printed circuit board and a liquid crystal display unit which the reliability of connection with a predetermined member using an anisotropic conductive binding material is improved. The multilayer printed circuit board is provided with a predetermined connection region for connecting with the predetermined member, and comprises a plurality of terminals formed and disposed in the predetermined connection region and connected to each wiring formed on the multilayer printed circuit board, and at least one dummy wiring which is formed on a different layer from the layer on which the terminals are formed, and the dummy wiring is disposed in a corresponding area between the neighboring terminals.

### RELATED APPLICATIONS

This application is based on Japanese Patent Application No. JP 2006-145529 filed on May 25, 2006, and including a specification, claims, drawings and summary. The disclosure of the above Japanese Patent Application is incorporated herein by reference in its entirety

### BACKGROUND OF THE INVENTION

1 . Field of the Invention

The present invention relates to a multilayer printed circuit board and a liquid crystal display unit, in particular, relates to the structure of the multilayer printed circuit board connected to the liquid crystal panel and a liquid crystal display unit in which the multilayer printed circuit board and the liquid crystal panel are connected.

2 . Description of the Related Art

A liquid crystal display unit is featured by low power consumption, and is used in the various fields. The liquid crystal display unit generally includes the liquid crystal panel having liquid crystal sealed in a gap between a pair of glass substrates facing each other and a the backlight unit or the like that illuminates the liquid crystal panel. One of the glass substrates of the liquid crystal panel is connected to the multilayer printed circuit board via a TCP (Tape Carrier Package) which mounts driver IC or the like for driving the liquid crystal panel, and the power supply circuit is mounted on the multilayer printed circuit board. The glass substrate and the TCP, and also, the TCP and the multilayer printed circuit board are joined with an adhesive using anisotropic conductive binding material called ACF (Anisotropic Conductive Film)

FIG. 8 is, a magnified top view showing a part of the TCP connection region 206 provided at the edge portion of the conventional multilayer printed circuit board. As shown in FIG. 8, connection terminals 201 are disposed at the edge of substrate signal wirings 200 formed in the multilayer printed circuit board 300. The multilayer printed circuit board 300 and the TCP are bonded by the ACF each other at the TCP connection region 206, and the connection terminals 201 and the connection terminals disposed on the TCP are connected each other. The assembling technology of the liquid crystal display unit, especially for the assembling structure for joining the glass substrate and the TCP is described in documents such as Japanese Patent Application Laid-Open No. 2002-314212 (pp. 6-10, FIG. 2), “chapter 14 Module assembly technology” written by Yuko Kubota (issued by the electronic journal publication, Sep. 28, 1999, pp. 168-169), and “Volume 44, number 10 Electronic materials” October issue (issued by the industrial investigating committee publication, Oct. 1, 2005, pp. 78-79).

As mentioned above, the TCP and the multilayer printed circuit board are bonded using the anisotropic conductive binding material called the ACF. The ACF is formed by dispersing electrically conductive particles in a thermosetting adhesive. After the ACF is placed on one of the substrates (e.g., the multilayer printed circuit board) and other substrate (e.g., the TCP) is arranged on an opposing relation to the multilayer printed circuit board, the thermosetting adhesive of the ACF is solidified by hot pressing (heating the ACF while being pressed to the connecting terminals). As the result, high electric conductivity and mechanical fixing strength can be obtained between respective connecting terminals of the multilayer printed circuit board and the TCP.

Here, the ACF is a resin which starts solidifying at the specific temperature. Therefore, for obtaining firm adhesion of the TCP and the multilayer printed circuit board by the ACF, heating and pressing added to the ACF need to be kept uniform over the connection region 206. However, connection terminals 201 in the connection region 206 can easily radiate heat while the ACF is heated compared with the substrate material members located between the connection terminals 201 because the connection terminals 201 are made of metal and are connected to the substrate signal wirings 200. As the result, a heat distribution over the TCP connection region 206 becomes nonuniform state and a thermal deformation in the ACF occurs, which causes a problem of loose contact, that is, the reliability of the connection has degraded.

The above-mentioned problem may occur not only for the case when the TCP and the multilayer printed circuit board are connected, but the case when the COF (Chip On Film) or FPC (Flexible Printed Circuit) and the multilayer printed circuit board are connected using the ACF.

Although disclosed in the above-mentioned related art about the assembling structure of the liquid crystal display unit, it is not disclosed about a structure which resolves nonuniformity of heat distribution over the TCP connection region by keeping heat and press added to the ACF uniform over the connection region.

### SUMMARY OF THE INVENTION

The present invention was made to solve the foregoing and other exemplary problems, drawbacks, and disadvantages. Exemplary feature of the present invention is to provide the multilayer printed circuit board and the liquid crystal display unit having the multilayer printed circuit board which can improve the reliability of the connection with the TCP, the COF or the FPC by preventing the thermosetting anisotropic conductive binding material from thermal deformation.

The multilayer printed circuit board connected to a predetermined member in a predetermined connection region by an anisotropic conductive binding material according to the present invention comprises a plurality of terminals which are formed and disposed in the predetermined connection region and connected to each wiring formed on the multilayer printed circuit board, and at least one dummy wiring which is formed on a layer of the multilayer printed circuit board different from the layer on which the terminals are formed, and the dummy wiring is disposed in a corresponding area between the neighboring terminals.

The liquid crystal display unit according to the present invention comprises a liquid crystal panel in which liquid crystal is sealed in a gap between a pair of substrates facing each other, at least one multilayer printed circuit board which is provided with electronic circuits for controlling the liquid crystal panel, and at least one predetermined member which is placed between the liquid crystal panel and the multilayer printed circuit board for connecting the liquid crystal panel with the multilayer printed circuit board electrically and physically, and the predetermined member is connected with the multilayer printed circuit board in a predetermined connection region provided on a top layer of the multilayer printed circuit board by using an anisotropic conductive binding material, wherein the multilayer printed circuit board comprises a plurality of terminals which are formed and disposed in the predetermined connection region, and connected to each wiring formed on the multilayer printed circuit board and at least one dummy wiring which is formed on a different layer from the layer on which the terminals are formed, and disposed in a corresponding area between the neighboring terminals.

With the above mentioned structure, according to the present invention, it is possible to improve the reliability of the connection in the structure that connects the multilayer printed circuit board and the TCP, the COF or the FPC using the thermosetting ACF.

Other exemplary features and advantages of the present invention will be apparent from the following description taken in conjunction with the accompanying drawings, in which like reference characters designate the same or similar parts throughout the figures thereof.

### BRIEF DESCRIPTION OF THE DRAWINGS

Exemplary features and advantages of the present invention will become apparent from the following detailed description when taken with the accompanying drawings in which:

FIG. 1 is a top view showing the structure of a liquid crystal display unit according to a first embodiment of the present invention;

FIG. 2 is a top view showing the structure of a TCP connection region of the multilayer printed circuit board according to the embodiment;

FIG. 3 is a sectional view showing the structure of the TCP connection region of the multilayer printed circuit board according to the embodiment;

FIG. 4 is a top view showing the structure of the TCP connection region of the multilayer printed circuit board according to the second embodiment of the present invention;

FIG. 5 is a top view showing the structure of the TCP connection region of the multilayer printed circuit board according to the third embodiment of the present invention;

FIG. 6 is a top view showing the structure of the TCP connection region of the multilayer printed circuit board according to the fourth embodiment of the present invention;

FIG. 7 is a top view showing the structure of the TCP connection region of the multilayer printed circuit board according to the fifth embodiment of the present invention; and

FIG. 8 is a top view showing the structure of the TCP connection region of the conventional multilayer printed circuit board.

### DETAILED DESCRIPTION OF THE EXEMPLARY EMBODIMENTS

The liquid crystal panel and the multilayer printed circuit board are connected via the TCP, the COF or the FPC which mount driver IC or the like as foregoing described in the related art. For the connection between the multilayer printed circuit board and the TCP, the COF or the FPC, the ACF or the like is used. The ACF is solidified by heating and pressing. Accordingly, the reliability of the connection is degraded due to the thermal deformation of the ACF if the heat distribution over the connection region of the multilayer printed circuit board is nonuniform.

Nonuniformity of the heat distribution is caused by the thermal conductivity differential over an area in which different materials are disposed such as the substrate made of the material having the low thermal conductivity, e.g. the glass epoxy, and the substrate signal terminals made of the metal having the high thermal conductivity. In order to avoid nonuniformity of the heat distribution, the structure can be considered that some metal materials are also disposed in the area between the substrate signal terminals as dummy wirings. However, if the dummy wirings are disposed in the same layer as the layer where the substrate signal terminals are disposed, the connection reliability rather declines because the substrate signal terminals disposed side-by-side can easily short-circuit via dummy wirings.

Accordingly, in the present invention, in the connection region with the TCP on the multilayer printed circuit board, dummy wirings are disposed not on the same layer as the layer where the substrate signal terminals are, but in the area including at least part between the neighboring substrate signal terminals, and on the different layer from the layer where the substrate signal terminals are, such as the layer under the substrate signal terminals, or the wiring layer inside or back of the multilayer printed circuit board.

Also, it can be possible to improve a heat radiation from the front surface or back surface of the multilayer printed circuit board by connecting the dummy wirings to the Lands formed on the front surface or back surface via through holes. Or, it also can be possible to improve a heat radiation from the end face by prolonging the dummy wirings to the end face of the multilayer printed circuit board. As the result, when the multilayer printed circuit board and the TCP, the COF or the FPC are connected using the ACF, uniformity of the heat distribution over the connection region can be realized. Accordingly, it can be possible to prevent the degradation of the connection reliability caused by the speed differences in solidifying of the ACF.

Hereinafter, the present invention will be described in detail based on the embodiments.

### Exemplary Embodiment 1

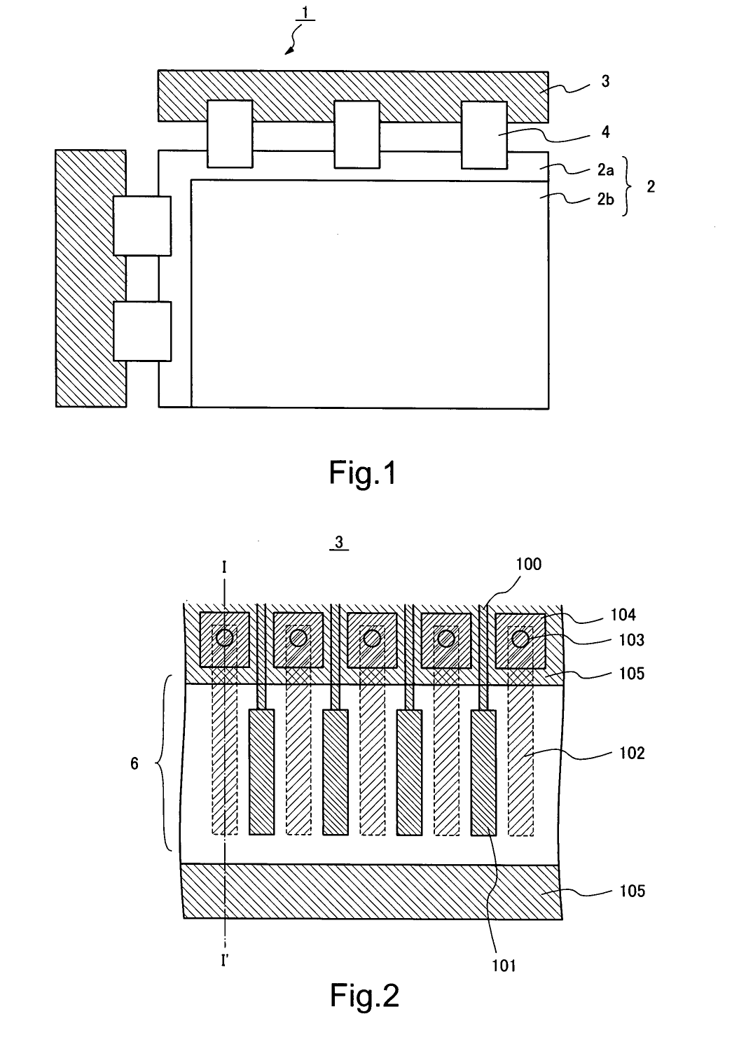

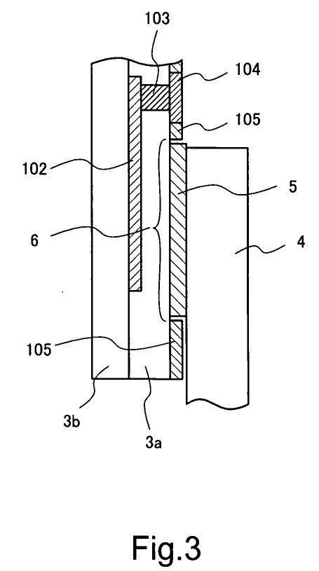

The first embodiment of the present invention will be described more in detail with reference to FIGS. 1 to 3. FIG. 1 is a top view showing the structure of the liquid crystal display unit according to the first embodiment of the present invention. FIG. 2 is a magnified top view showing a part of the connection region provided on the multilayer printed circuit board for connecting with the TCP according to the first embodiment. FIG. 3 is a sectional view showing the structure of the multilayer printed circuit board according to the first embodiment.

As shown in FIG. 1, the liquid crystal display unit according to the first embodiment includes a liquid crystal panel 2, a backlight unit and a case (not shown). The liquid crystal panel 2 includes an active matrix board (hereinafter, referred to as the TFT substrate 2a) on which the switching element such as TFT (Thin Film transistor) or the like is formed, the opposed substrate 2b on which a color filter and a black matrix or the like is formed, and liquid crystal sealed in a gap between the TFT substrate 2a and the opposed substrate 2b. The TFT substrate 2a includes a display area on which pixels, each of pixels are surrounded and formed by scanning lines (gate lines) and signal lines (drain lines) each approximately crossing at right angles, are arranged by a matrix shape. A terminal area is formed outside the display area. And one side of the TCP 4 which mounts driver IC is connected to the terminal area using the ACF electrically and physically. The other side of the TCP 4 is connected to the multilayer printed circuit board 3, on which the power supply circuit or the like are formed, using the ACF electrically and physically.

Note that FIG. 1 is just an illustration and each size, the arrangement and the quantity of the liquid crystal panel 2, the multilayer printed circuit board 3 and the TCP 4 are optional. Although FIG. 1 shows that the liquid crystal panel 2 and the multilayer printed circuit board 3 are connected via the TCP 4, the liquid crystal panel 2 and the multilayer printed circuit board 3 may be connected via COF or FPC. For connecting the TCP 4 and the liquid crystal panel 2, or for connecting the TCP 4 and the multilayer printed circuit board 3, NCF (Non Conductive Film) can be used, not just using the ACF.

Next, the structure of the multilayer printed circuit board 3 which is a characterizing portion of the first embodiment will be described with reference to FIG. 2 and FIG. 3. FIG. 2 is a magnified top view showing a part of the edge portion of the multilayer printed circuit board 3 to be connected with the TCP. FIG. 3 is a sectional view taken along I-I′ line of FIG. 2.

The multilayer printed circuit board 3 according to the first embodiment is mounted with various circuit elements (not shown) required for driving and controlling the liquid crystal panel 2. As shown in FIG. 2 and FIG. 3, the TCP connection region 6 for connecting with the TCP 4 is provided at the peripheral area of these circuit elements, mainly at the edge portion of the top layer of the multilayer printed circuit board 3. As shown in FIG. 2 and FIG. 3, a protection film 105, for electrically insulating and protecting the surface of the wiring layer by a coating resin such as resist resin, is formed on the surface of the upper substrate 3a of the multilayer printed circuit board 3 except the TCP connection region 6. The above-mentioned circuit elements are connected to substrate signal wirings 100. Each substrate signal wiring 100 is connected to the substrate signal terminal 101 disposed in the TCP connection region 6.

As shown in FIG. 2 and FIG. 3, in the multilayer printed circuit board 3, dummy wirings 102 made of metal materials are formed in the area including at least a part between the neighboring substrate signal terminals 101 and on the under layer than the layer where the substrate signal terminals are, i.e., the under layer than the top layer where the TCP connection region 6 is provided. A metal material which forms the dummy wirings 102 may be the same material as the substrate signal terminals 101 or may not be. The dummy wirings 102 are connected to the top layer of the multilayer printed circuit board 3, that is, they are connected to the metallic area (the Land 104) formed on the same layer as the substrate signal terminals 101 via through holes 103. In order to prevent the substrate signal terminals 101 and the Land 104 from short-circuiting through the ACF 5, as shown in FIG. 2, the Lands 104 are formed at the inner side than the TCP connection region 6, that is, the area on the side away from the liquid crystal panel 2.

The multilayer printed circuit board 3 is connected with the TCP 4 using the ACF 5 as follows. The ACF 5 is put between the multilayer printed circuit board 3 and the TCP 4 at the TCP connection region 6. And the ACF 5 is solidified by hot pressing using a predetermined jig. In this case, in the structure according to the first embodiment, heat which is applied for solidifying the ACF 5 radiates via substrate signal wirings 100 around the area near the substrate signal terminals 101. Also, because the dummy wirings 102 are disposed at each area between substrate signal terminals 101 as shown in FIG. 2, the heat is radiated from dummy wirings 102 via the through holes 103 and the Lands 104 around the area between each substrate signal terminal 101. As the result, it can be possible to keep the heat distribution approximately uniform during solidifying the ACF 5 over the surface in the TCP connection region 6. Accordingly, it can be possible to prevent the ACF 5 from thermal deforming, and thus to improve the reliability of the connection.

Note that, a method of manufacturing dummy wirings 102 in the multilayer printed circuit board 3 is not limited in particular. For example, manufacturers may pattern dummy wirings 102 when they produce substratum wirings of the multilayer printed circuit board 3 using a method to remove unnecessary parts by an etching called Subtractive Process. By this method, dummy wiring 102 can be formed easily.

The shape, the interval and the location of each substrate signal terminal 101 and each substrate signal wiring 100 may be arbitrarily arranged. Although FIG. 3 shows the multilayer printed circuit board 3 which comprises an upper substrate 3a and a substratum substrate 3b, and the substrate signal terminals 101, the substrate signal wirings 100 and the Lands 104 are provided on the surface side of the upper substrate 3a, that is, the side where the TCP 4 is connected, the multilayer printed circuit board 3 is not limited to this structure. The multilayer printed circuit board 3 should have at least two wiring layers and be providing the substrate signal terminals 101 and dummy wirings 102 on the different layers. Although FIG. 3 shows the multilayer printed circuit board 3 in which connection between each dummy wiring 102 and the surface of the top layer (the side of substrate signal terminal 101) is provided via through hole 103, it may be possible to provide connection between each dummy wiring 102 and the surface of the bottom layer (the back side of the substratum substrate 3b) via through hole (a formed place does not care). Or both of connections may be possible. Also, it may be possible for the multilayer printed circuit board 3 to provide only dummy wiring 102 without connection via the through hole 103 and the Land 104.

In the TCP connection region 6 provided at the edge of the multilayer printed circuit board 3 to be connected to the liquid crystal panel 2 via the TCP 4 or the like, the dummy wirings 102 are disposed in the area including at least part between the neighboring substrate signal terminals and on the different layer from the layer where the substrate signal terminals exist, such as the under layer of the layer where the substrate signal terminals exist. Also, the dummy wirings 102 are connected with the Lands 104 formed on the surface of the top layer or the bottom layer of the substrate via through holes 103. By this structure, the heat radiation effect in the area around the substrate signal terminals 101 and the heat radiation effect in the area between the substrate signal terminals 101 can be approximately equal. Accordingly, when the TCP 4 and the multilayer printed circuit board 3 are connected with each other using thermoset members such as the ACF 5, it can be possible to prevent the ACF 5 from thermal deforming, and thus to improve the reliability of the connection.

### Exemplary Embodiment 2

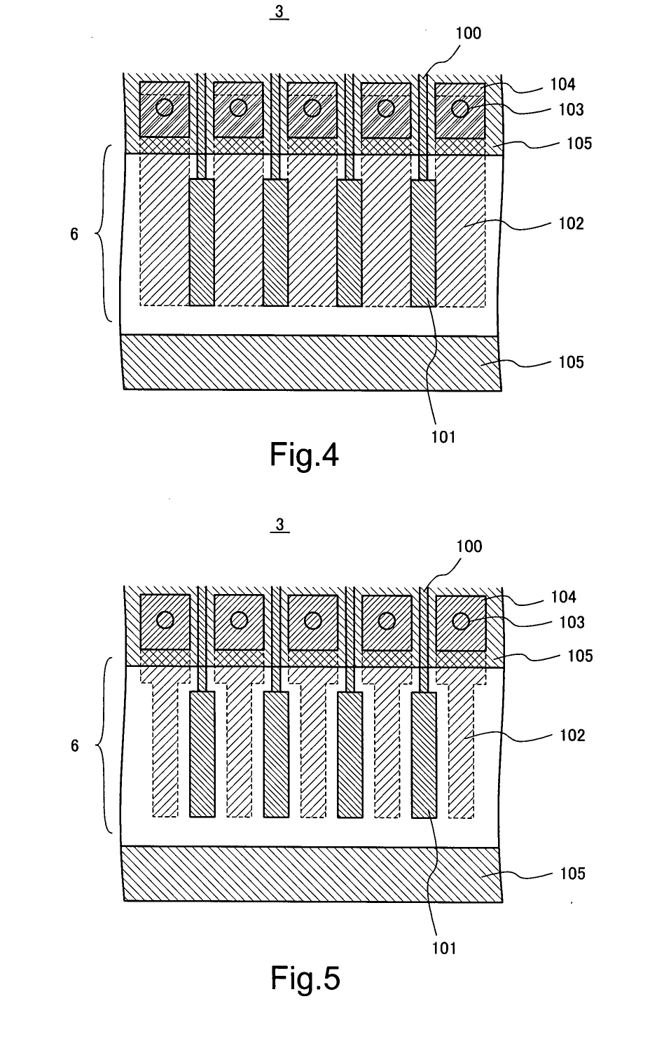

FIG. 4 is a top view showing the structure of the multilayer printed circuit board according to the second embodiment of the present invention. Although FIG. 2 shows the structure that the dummy wirings 102 are formed in the area including at least part between the neighboring substrate signal terminals, it shows the structure that the dummy wirings 102 are formed in all area between the each substrate signal terminal 101 in this second embodiment. Because the substrate signal terminals 101 and dummy wirings 102 are disposed on the different layers each other, even if the each width of the dummy wiring 102 is made wide, short-circuiting between the dummy wirings 102 and the substrate signal terminals 101 does not occur. The dummy wirings 102 may be made wider as they lap over partially with the substrate signal terminals 101 when they are seen from the surface. Thus, by forming dummy wirings 102 wider than that of formed on the multilayer printed circuit board according to the first embodiment, it can be possible to keep the thermal distribution approximately uniform during solidifying the ACF 5 over the surface in the TCP connection region 6.

### Exemplary Embodiment 3

FIG. 5 is a top view showing the structure of the multilayer printed circuit board according to the third embodiment of the present invention. Although it shows in FIG. 2 that the shape of each dummy wiring 102 is rectangular, the shape-of the dummy wiring 102 may be arbitrarily arranged. For example, as shown in FIG. 5, each dummy wiring 102 may have a shape so as to maintain a constant distance of interval with the neighboring substrate signal wiring 100 and interval with the substrate signal terminal 101. Due to such shape, it can be possible to improve the uniformity of thermal distribution in the TCP connection region 6. Also, the shape of each dummy wiring 102 may be altered and dummy wirings 102 may be formed to cover whole area of the TCP connection region 6 when seen from the surface.

### Exemplary Embodiment 4

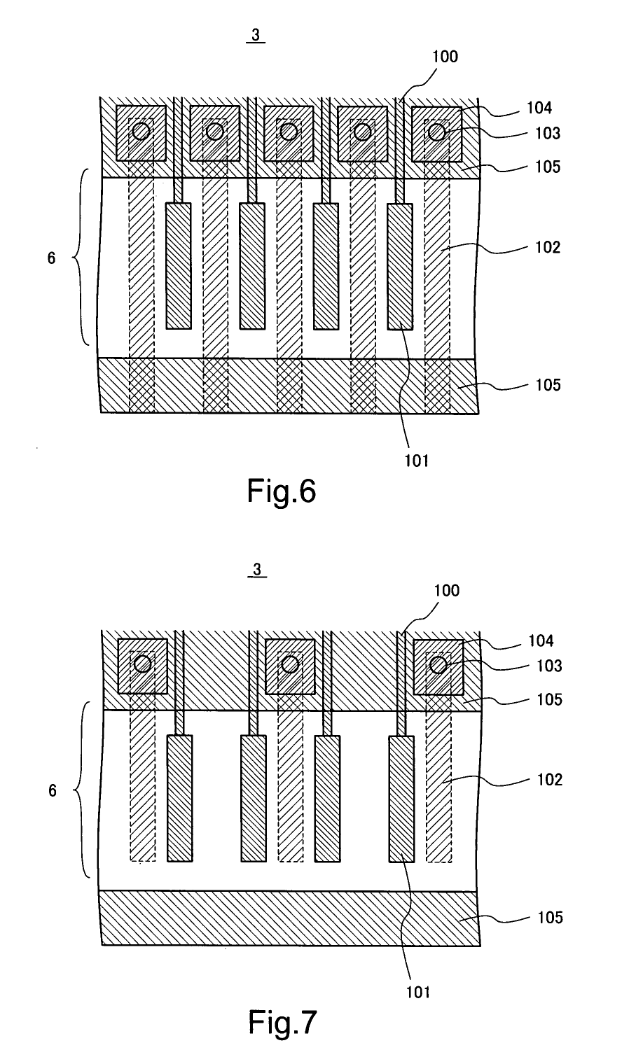

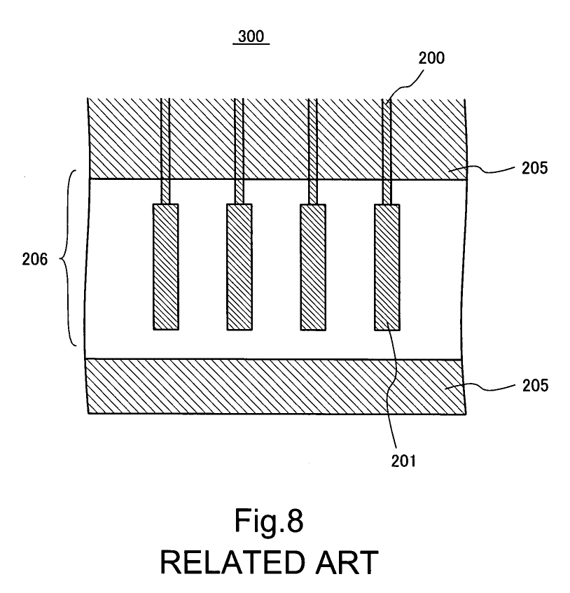

FIG. 6 is a top view showing the structure of the multilayer printed circuit board according to the fourth embodiment of the present invention. FIG. 2 shows that dummy wirings 102 are connected to the Lands 104 via through holes 103 so that heat absorbed by dummy wirings 102 can be radiated outside. As shown in FIG. 6, in addition to the structure shown in FIG. 2, the dummy wirings 102 can be extended to the end of the multilayer printed circuit board 3 and be exposed. Due to the structure, it can be possible to radiate heat absorbed by dummy wirings 102 also at the end of the multilayer printed circuit board 3.

### Exemplary Embodiment 5

FIG. 7 is a top view showing the structure of the multilayer printed circuit board according to the fifth embodiment of the present invention. FIG. 2 shows that dummy wirings 102 are disposed at locations between all substrate signal terminals 101. In contrast, as shown in FIG. 7, dummy wiring 102 may be disposed at locations only between the certain substrate signal terminals 101. As a result, it can be possible to reduce the cost to provide the dummy wirings 102. Furthermore, it may be arbitrarily arranged to combine any of the structures shown in FIG. 2, FIGS. 4 to 7.

Note that, although the foregoing embodiments show the cases where the multilayer printed circuit board 3 according to the present invention is used for the liquid crystal display unit, the present invention is not limited to the foregoing embodiments, and it can be applied to any kind of multilayer printed circuit boards connected to other members using thermoset members.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments without the use of inventive faculty. Therefore, the present invention is not intended to be limited to the embodiments described herein but is to be accorded the widest scope as defined by the limitations of the claims and equivalents.

Further, it is noted that the inventor's intent is to retain all equivalents of the claimed invention even if the claims are amended during prosecution.

While this invention has been described in connection with certain preferred embodiments, it is to be understood that the subject matter encompassed by way of this invention is not to be limited to those specific embodiments. On the contrary, it is intended for the subject matter of the invention to include all alternative, modification and equivalents as can be included within the spirit and scope of the following claims.

Further, it is the inventor's intention to retain all equivalents of the claimed invention even if the claims are amended during prosecution.

What is claimed is:

1. A multilayer printed circuit board connected to a predetermined member in a predetermined connection region by an anisotropic conductive binding material comprising:
a plurality of terminals which are formed and disposed in the predetermined connection region, and connected to each wiring formed on the multilayer printed circuit board; and
at least one dummy wiring which is formed on a layer of the multilayer printed circuit board different from the layer on which the terminals are formed, and disposed in a corresponding area between the neighboring terminals.

2. The multilayer printed circuit board according to the claim 1, wherein
said dummy wiring is connected via a through hole to a land made of metal which is formed on a surface of the same layer of the multilayer printed circuit board as the layer on which said terminals are formed, and disposed in an area outside said predetermined connection region.

3. The multilayer printed circuit board according to the claim 2, wherein
said land is formed on a surface of layer which locates at opposite side of the layer on which said terminals are formed.

4. The multilayer printed circuit board according to the claim 1, wherein
said dummy wiring occupies all corresponding area between the neighboring terminals.

5. The multilayer printed circuit board according to the claim 1, wherein
said dummy wiring has a shape for maintaining a constant distance of an interval with said terminal and an interval with said wiring connected to said terminal.

6. The multilayer printed circuit board according to the claim 1, wherein
said dummy wiring is formed to be exposed to the end of said multilayer printed circuit board.

7. A liquid crystal display unit comprising:
a liquid crystal panel in which liquid crystal is sealed in a gap between a pair of substrates facing each other;
at least one multilayer printed circuit board which is provided with electronic circuits for controlling said liquid crystal panel; and
at least one predetermined member which is placed between said liquid crystal panel and said multilayer printed circuit board for connecting said liquid crystal panel with said multilayer printed circuit board electrically and physically, and is connected with said multilayer printed circuit board in a predetermined connection region provided on a top layer of said multilayer printed circuit board by using an anisotropic conductive binding material,
wherein, said multilayer printed circuit board comprising:
a plurality of terminals which are formed and disposed in the predetermined connection region, and connected to each wiring formed on the multilayer printed circuit board; and
at least one dummy wiring which is formed on a different layer from the layer on which said terminals are formed, and disposed in a corresponding area between the neighboring terminals.

8. The liquid crystal display unit according to the claim 7, wherein
said dummy wiring is connected via a through hole to a land made of metal which is formed on a surface of the same layer of the multilayer printed circuit board as the layer on which said terminals are formed, and disposed in an area outside said predetermined connection region.

9. The liquid crystal display unit according to the claim 8, wherein
said land is formed on a surface of layer which locates at opposite side of the layer on which said terminals are formed.

10. The liquid crystal display unit according to the claim 7, wherein
said dummy wiring occupies all corresponding area between the neighboring terminals.

11. The liquid crystal display unit according to the claim 7, wherein
said dummy wiring has a shape for maintaining a constant distance of an interval with said terminal and an interval with said wiring connected to said terminal.

12. The liquid crystal display unit according to the claim 7, wherein
said dummy wiring is formed to be exposed to the end of said multilayer printed circuit board.

13. The liquid crystal display unit according to the claim 7, wherein
said predetermined member is the Tape Carrier Package, the Chip On Film or the Flexible Printed Circuit.
